(19) United States
(12) Patent Application Publication
(10) Pub. No.: US 2003/0034175 A1
(43) Pub. Date: Feb. 20, 2003

(54) Configurations and methods for improved copper distribution uniformity in printed wiring boards

(75) Inventors: Henry Johnson, Elk Mound, WI (US); James P. Augustine, Chippewa Falls, WI (US)

Correspondence Address: Honeywell International Inc., 101 Columbia Road, PO Box 2245, Morristown, NJ, 07962, US

(73) Assignee: Honeywell Advanced Circuits, Inc.

(21) Appl. No.: 09/933,596

(22) Filed: Aug. 20, 2001

(51) Int. Cl. H05K 1/11

(52) U.S. Cl. 174/262

(57) ABSTRACT

An electronic device has a dielectric substrate with first and second surface and a via through the substrate connecting the first and second surfaces. A first and second sacrificial copper structure surrounds the via on the first and second surfaces, respectively, wherein each of the sacrificial structures covers an area of less than three times the horizontal cross sectional area of the via. Contemplated sacrificial structures are preferably formed in a photolithographic process.

### FIELD OF THE INVENTION

The field of the invention is electronic devices and their manufacture.

### BACKGROUND OF THE INVENTION

Printed wiring boards frequently require through-hole plating, conductive or non-conductive via filling, and electrolytic nickel and gold plating, wherein the gold plating often serves as an etch resist. While employing a gold layer as an etch resist may eliminate otherwise necessary processing steps, other problems may arise.

For example, in a typical prior art process for manufacture of a printed wiring board (PWB), a panel with a base copper foil is drilled and sensitized. In a subsequent step, copper is deposited onto the surface of the through-hole to the required thickness via copper panel plating. At this time no circuit pattern is defined using photoresist, and the entire panel surface is copper plated. Copper panel plating of drilled and sensitized panels advantageously provides a relatively smooth and uniform surface in the copper plated via, however, it tends to increase difficulties in further processing steps.

Among other things, since the minimum plated copper thickness is generally specified for the through-holes (typically between 0.0008″ to 0.0015″), an equivalent-or higher amount is plated on the surface of the panel due to less efficient plating in the through-holes. Consequently, the total surface copper thickness often exceeds a desirable or even tolerable thickness. Moreover, excessive total surface copper thickness may lead to yet further difficulties. For example, a chemical etching step after via filling, nickel and gold plating will not only etch copper perpendicular to the panel, but also laterally, which is especially problematic when the total surface copper thickness is relatively high. Thus, an increasing copper thickness will typically result in increased “undercut” underneath the nickel and gold layer during the circuit definition etching process, often leading to a nickel/gold overhang causing “slivers” that may break off and create shorting of adjacent circuit paths.

To overcome at least some of the problems associated with excessive total surface copper thickness, surface copper can be mechanically reduced by scrubbing or sanding the surface of the panel, or chemically reduced by a variety of etching processes. Mechanical reduction of surface copper advantageously also removes via fill material, which would otherwise protrude from the surface as the surrounding copper is removed by a chemical process. However, mechanical reduction of copper is generally labor-intensive and often leads to relatively large variations in copper thickness across the surface of the panel, which in turn tends to create problems in circuit definition, and generally increases manufacturing variability.

Although there are various configurations and methods known in the art to improve copper distribution uniformity in printed wiring boards, all or almost all of them suffer from one or more disadvantages. Therefore, there is still a need to provide improved configurations and methods for improved copper distribution uniformity in printed wiring boards.

### SUMMARY OF THE INVENTION

The present invention is directed to apparatus and methods in which an electronic device has a dielectric substrate with a first and a second surface, and in which the substrate has a via through the substrate connecting the first and second surface. A first and a second sacrificial copper structure are coupled to the first and the second surface and surround the via, respectively, wherein each of the sacrificial copper structures covers an area of no more than three times, more preferably no more than two times, the horizontal cross sectional area of the via, and wherein contemplated sacrificial copper structures are formed on the substrate via a photolithographic process.

In one aspect of the inventive subject matter, a copper layer may be disposed on the first or second surface of the dielectric substrate and/or the surface of the via. In especially contemplated aspects, the copper layer on the via and the sacrificial copper structure are formed in a single process, and preferred sacrificial copper structures have a diameter that is about 150 microns larger than the via diameter.

In another aspect of the inventive subject matter, the via is filled with a conductive or nonconductive fill material, preferably a resin, and the via fill material may further be disposed on the substrate in an area other than the via. It is further contemplated that a photoresist layer may be placed between the first and/or second surface and the via fill material.

In a further aspect of the inventive subject matter, a method of forming an electronic device has one step in which a dielectric substrate with a first surface and a second surface is provided. In a further step, a via is formed in the substrate connecting the first and second surface. In a still further step, a first and a second sacrificial copper structure are formed in a photolithographic process on the first and the second surface, wherein each of the first and second sacrificial copper structures covers an area of no more than three times the horizontal cross sectional area of the via. In yet a further step, the via is filled with a via fill material, and in another step, the first and second sacrificial copper structures are removed from the substrate.

Various objects, features, aspects and advantages of the present invention will become more apparent from the following detailed description of preferred embodiments of the invention, along with the accompanying drawing.

### BRIEF DESCRIPTION OF THE DRAWINGS

FIG. 1 is a schematic side view of one exemplary electronic device according to the inventive subject matter.

FIG. 2 is a schematic top view of the device of FIG. 1.

FIG. 3 is a schematic side view of another exemplary electronic device according to the inventive subject matter.

### DETAILED DESCRIPTION

Among other things, the inventors have discovered that problems associated with total surface copper thickness and “undercut” underneath a nickel and/or gold layer in an electronic device can be overcome by depositing onto the panel a sacrificial copper structure that surrounds the through-hole (i.e., the via).

Thus, an exemplary electronic device has a dielectric substrate with a first and second surface, and a via connecting the first and second surface, wherein the via has a horizontal cross sectional area. A first and a second sacrificial copper structure are coupled to the first and the second surface and surrounding the via, respectively, wherein each of the first and second sacrificial copper structures covers an area of no more than three times the horizontal cross sectional area of the via, and wherein the first and the second sacrificial copper structure are formed on the substrate via a photolithographic process.

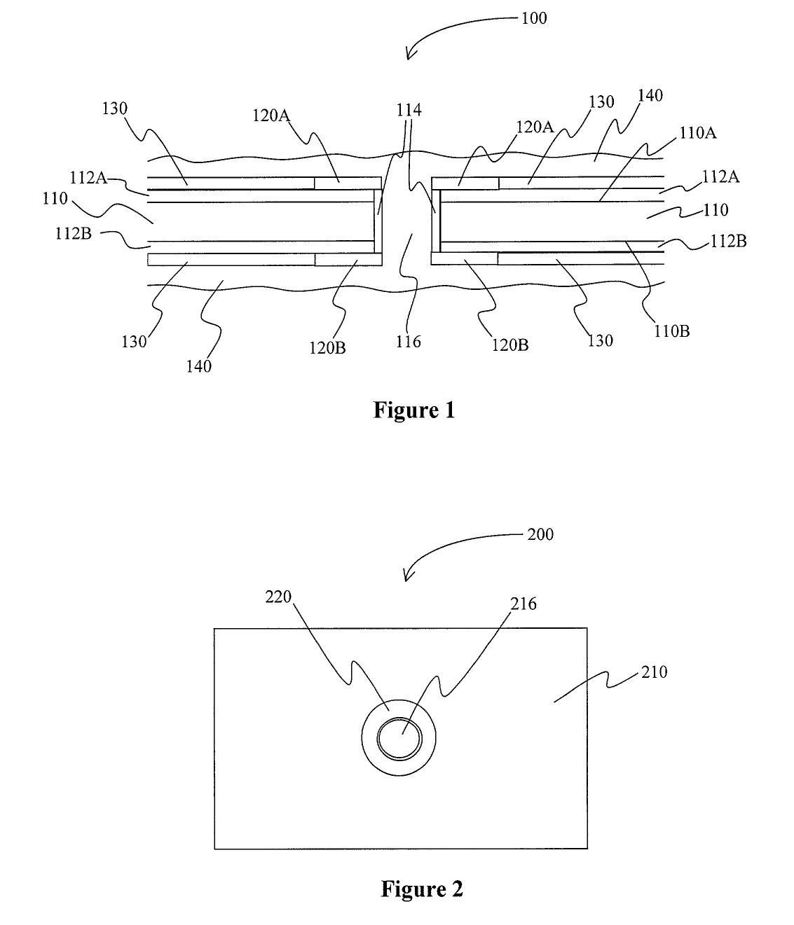

FIG. 1 illustrates an exemplary electronic device 100 in which a dielectric substrate 110 has first surface 110A and a second surface 110B that are both covered with a copper layer 112A and 112B. The surface of the through-hole 116 is covered with a copper layer 114. A first sacrificial copper structure 120A is disposed on the first surface 110A and surrounds the through-hole 116, and a second sacrificial copper structure 120B is disposed on the second surface 110B and surrounds the through-hole 116. Formation of the first and second sacrificial copper structures and of the copper layer 114 is typically performed simultaneously (however, the invention is not limited to simultaneous deposition). Photoresist layer 130 is disposed on the first and second copper layer 112A, 112B, and a via fill material 140 fills the through hole and is further disposed on the sacrificial copper structures and the photoresist layers.

It is generally contemplated that suitable electronic devices include all devices that have a printed wiring board (PWB), however, particularly contemplated devices are PWBs with copper plated through-holes and optional by an nickel and gold layer. Consequently, it is contemplated that the dielectric substrate comprises a material that is suitable for manufacture for PWBs, and especially contemplated materials include organic polymers, woven and non-woven glass and mineral fibers, which may or may not be reinforced with one or more resins. There are numerous suitable materials known in the art, and exemplary materials are described in U.S. Pat. No. 6,146,749 to Miyamoto et al., U.S. Pat. No. 6,214,923 to Goto et al, and U.S. Pat. No. 6,229,096 to Gaku et al. Particularly preferred materials are lasable, and exemplary lasable materials are described in U.S. Pat. No. 6,224,965 to Haas et al., all of which are incorporated by reference herein.

Further contemplated dielectric substrates include at least one copper layer, which may be disposed on the first or second surface of the substrate, and it is especially preferred that the dielectric substrate has a continuous copper layer on both the first and the second surface. The term “surface” as used herein generally refers to the upper and/or lower portions of the substrate onto which electrically conductive traces are formed in one or more subsequent process steps.

The thickness of contemplated copper (comprising typically at least 85 wt % copper) layers is typically between 20 and 30 microns. However, where thicker copper layers are desired, contemplated copper layers may also have a thickness between about 30 and 60 microns, and even more. On the other hand, and especially where the number of subsequent planarization steps should be minimized, copper layers with a thickness of between 10 to 20 microns, and even less are also contemplated. Suitable copper layers are typically laminated onto the substrate, however, it should be appreciated that all other manners of coupling a copper layer to the substrate are also contemplated.

With respect to the through-hole, it is contemplated that all forms, diameters and configurations are suitable for use in conjunction with the teachings presented herein, so long as the through holes are configured to receive a metal layer (preferably copper), and connect a first surface of the substrate to a second surface of the substrate. As used herein, the term “through-hole connects a first surface of the substrate to a second surface of the substrate” means that the through-hole is contiguous between the first and second surfaces, wherein onto at least one of the first and second surfaces electrically conductive traces are formed in one or more subsequent steps. Thus, and especially where relatively large vias are desired, contemplated through-holes may have a diameter between about 800-2000 microns, and even more. On the other hand, smaller vias are also contemplated, and suitable via diameters include 400-800 microns, and even 100-400 microns or less. More preferably, through holes will have a via diameter of about 300 microns (±20 microns). FIG. 2 depicts a top view of an exemplary through-hole surrounded by a sacrificial copper structure in a dielectric substrate. Here, electronic device 200 has a dielectric substrate 210 with a via 216, and a sacrificial copper structure 220 that surrounds the via 216.

Contemplated vias may be formed by various methods, and all known methods of forming a via are deemed appropriate, and particularly include drilling and lasing. With respect to the number of contemplated vias in a substrate, it should be appreciated that the number of vias is not limiting to the inventive subject matter. Thus, the number of vias in a substrate may be between a single via and several hundred vias, and where appropriate, between several hundred and several thousand vias, or more.

In further particularly contemplated aspects of the inventive subject matter, the sacrificial copper structure is formed on the copper layer of the substrate in a standard photolithographic process using negative or positive photoresist, and a mask that transfers an image of the sacrificial copper structure onto the substrate. After developing of the photoresist, copper is preferably pattern plated onto the substrate separately from, or more preferably simultaneously with the copper deposition onto the surface of the through-holes. There are numerous photolithographic processes for formation of a copper structure known in the art, and various exemplary suitable processes are described in U.S. Pat. No. 6,212,769 to Boyko et al., U.S. Pat. No. 6,156,221 to Lauffer et al., and U.S. Pat. No. 5,948,592 to Umehara et al.

As used herein, the term “sacrificial copper structure” refers to a copper structure that at least partially surrounds a via, that is at least partially (and more typically completely) removed in a following process step, and that covers an area that is no larger than 5 times, more preferably no larger than 3 times, and most preferably no larger than two times the area of the horizontal cross section of the via. For example, where the via cross-sectional area is 800 microns², contemplated sacrificial copper structures will cover an area of the substrate of no larger than 4000 microns², more preferably no more than 2400 microns², and most preferably no more than 1600 microns². In contrast, a copper layer deposited onto the entire surface of the substrate is not considered a sacrificial copper structure because the entire surface of the substrate is larger than five times the area of the horizontal cross section of the via.

In further aspects of the inventive subject matter, the sacrificial copper structure may include metals other than copper (or in some cases no copper at all), and especially contemplated metals include metals and alloys with a substantial difference (i.e. at least 10%, more preferably at least 25%) in etch resistance relative to gold or nickel. Further contemplated metals include silver, aluminum, and titanium. With respect to the amount of alternative metals it should be appreciated that a particular amount will generally depend on the particular metal included. For example, while some sacrificial copper structures may comprise between 2-8 wt % aluminum, other sacrificial copper structures may comprise 20-25 wt % silver. It is still further contemplated that, where appropriate, copper may entirely replaced by an alternative metal. Alternatively, polymers may be employed in place of copper, wherein the polymer can be selectively and controlled deposited onto the substrate, and wherein the polymer can selectively removed from the substrate. In still further aspects of the inventive subject matter, the sacrificial copper structure is deposited in a process other than a photolithographic process, and alternative processes include printing and electroless plating.

With respect to the shape of contemplated sacrificial copper structures, it should be appreciated that various shapes other than a toroid or round shape are also contemplated. For example, suitable shapes include elliptic shapes, square and rectangular shapes, and irregular shapes. Similarly, it is contemplated that the thickness of appropriate sacrificial copper structures may vary considerably. However, it is generally contemplated that the thickness will be in the range of the thickness of the layer in the through hole or slightly (i.e., up to about 15%) thicker. Therefore, particularly contemplated thickness is between about one and 500 microns, more typically in the range of between about 5 and 60 microns, and most typically in the range of between 20 and 40 microns.

While it is generally preferred that contemplated sacrificial copper structures are deposited onto the first and the second surface of the substrate, it should also be appreciated that a sacrificial copper structure may also be deposited on only one surface. Similarly, it is generally preferred that the size and shape of contemplated sacrificial copper structures is substantially identical (i.e., within about 10% variation in the area that covers the substrate) among a plurality of sacrificial copper structures. However, where appropriate, sacrificial copper structures of differing sizes and/or shapes may also be formed on the substrate. For example, it is particularly contemplated that a sacrificial copper structure on the bottom of a substrate (here: panel for fabrication of a PWB) remains larger (e.g., about 150 microns larger in diameter) than the via diameter, while the sacrificial copper structure on the top side of the substrate is smaller than the sacrificial copper structure on the bottom of the substrate.

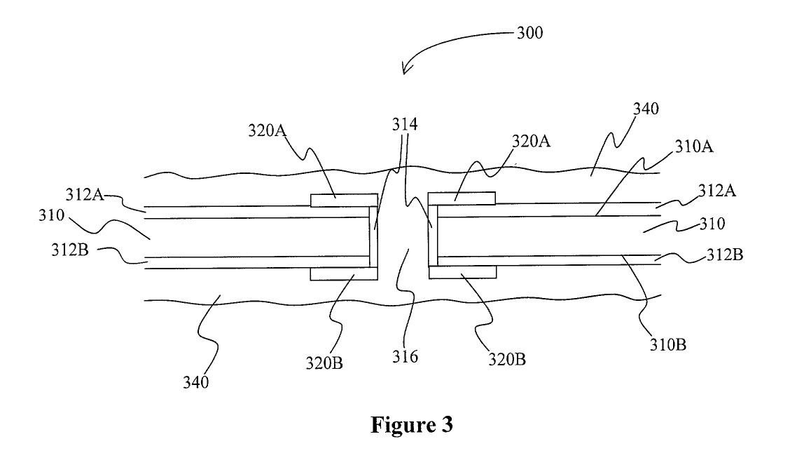

In further alternative aspects of the inventive subject matter, the photoresist layer is removed prior to via filling. Consequently, contemplated electronic devices will have a structure as depicted in FIG. 3, wherein like numerals are like components as in FIG. 1. Here, the photoresist layer has been stripped before the via filling process using standard protocols well known in the art. For ease of filling, it is contemplated that at least one side of the substrate may be sanded or otherwise planarized. Thus, it should be appreciated that contemplated electronic devices may or may not include a photoresist layer that is disposed between the via filling material and the surface of the substrate (which may or may not include an electrolytic copper layer).

With respect to the hole fill material, it is contemplated that all known hole fill materials are considered appropriate for use herein. Exemplary via fill materials are described in U.S. Pat. No. 6,085,415 to Gandhi et al., and U.S. Pat. No. 5,744,285 to Felten et al., both of which are incorporated by reference herein. For example, where it is desired that the hole fill material is electrically conductive, various metals (e.g., silver flakes, silver-coated copper, etc.) may be employed. On the other hand, where it is desired that the hole fill material is substantially electrically non-conductive, organic polymers or resins (e.g., cyanate esters, polyimides, polyetherimides, polybenzimidazoles, polyarylethers, polyethersulfones, aromatic polyamides, etc.) may be employed.

Regardless of the particular composition and electrical conductivity of the employed via fill materials, it is contemplated that the via fill material, the photoresist layer (if not stripped in a prior process), and the sacrificial copper structures on the first and second surfaces are removed using a planarization process (e.g., mechanical abrasion, chemical-mechanical-planarization, etc.). There are numerous planarization processes known in the art, and all of the known planarization processes are contemplated. It is further contemplated that after planarization the copper layer on the substrate is reduced to a thickness of about 15-20 microns or less (typically between 1-10 microns, and most typically no less than between 3-5 microns). It should be especially appreciated that by employing the sacrificial copper structures on the substrate, the copper thickness after planarization is substantially homogeneous, i.e., the copper thickness has a variability of less than 25 microns, more preferably less than 20 microns, and most preferably less than 15 microns.

Thus a method of fabricating an electronic device includes one step in which a dielectric substrate is provided having a first and a second surface. In another step, a via having horizontal cross sectional area is formed in the substrate connecting the first and second surfaces. In a further step, a first and a second sacrificial copper structure are formed in a photolithographic process on the first and the second surface and surrounding the via, respectively, wherein each of the first and second sacrificial copper structures covers an area of no more than three times the horizontal cross sectional area of the via, and in a still further step, the via is filled with a via fill material. In yet another step, at least part of the first and second sacrificial copper structures are removed from the substrate. With respect to all of the components and their interrelations of contemplated methods, the same considerations as described above apply.

### EXAMPLES

The following examples are intended to provide various exemplary aspects of the inventive subject matter. Unless indicated otherwise, all process steps were performed using standard equipment and protocols.

### Button Plate Process Without Removal of Photoresist

A panel with a plurality of through-holes was copper flash-plated with electrolytic copper to a thickness of approximately 0.0003″ (7.6 microns), a 0.002″ thick layer of photoresist was applied, and a pad was imaged around each through-hole. The imaged “button” or small pad measured 0.006″ (150 microns) larger in diameter than the drilled hole. The panels were then pattern-plated with copper to a finished thickness of 0.0015!″ in the through holes. The panels then had the via-filling process performed OVER the photoresist, and following a hole fill ink cure step, the panels were planarized to remove excess hole fill, the photoresist, and the surface copper to a thickness of 0.00064″-0.00084″. The panels were then processed through permanganate/electroless copper, and further processing steps as outlined below. The surface copper thickness distribution data were collected at the planarization step. The thickness ranged from 0.00048″ to 0.00102″. This method required multiple (up to 5) passes through the planarization equipment.

### Button Plate Process With Removal of Photoresist

The materials and process steps were substantially as described above, with the exception that the photoresist was stripped prior to the hole fill process. For ease of filling, it is contemplated that at least one side of the substrate may be sanded or otherwise planarized. Measurements taken after the planarization step and showed that the surface copper was more uniform and averaged 0.00055″ in thickness. Remarkably, only 2 “passes” through the planarization process were required.

### Button Dot Plate Process

The materials and process steps were substantially as described above, with the exception that the photoresist on one side of the substrate is imaged with a pad size that is approximately 0.002″ to 0.006″ larger than the through-hole (thereby generating a sacrificial structure [button] as described above) and the photoresist on the opposite side of the substrate is imaged with a substantially smaller pad size (typically a size smaller or the same as the size of the through-hole [dot]). Thus, it is contemplated that the structures generated with the button-dot process will simplify the planarization process since only one button need s to be removed from the substrate.

### Prior Art Process

The materials employed in the prior art process were substantially the same as described above. Vias were drilled into the dielectric substrate, then the substrate was metallized and subsequently panel plated, followed by hole fill step and controlled etch process. The copper surface was then planarized until the thickness was reduced to a target range of 0.0005″-0.0009″, followed by a desmear/electroless copper step. Photoresist was applied and the circuit pattern image was printed and developed, followed by a copper flash plating step, and subsequent plating of electrolytic nickel and gold layers. The photoresist was stripped and the substrate was then processed through an alkaline etch process. Copper thickness distribution data were collected at the post-holefill planarization step. The range of thickness was from less than 0.0004″ to nearly 0.0016″, despite multiple passes through the planarization equipment.

Thus, specific embodiments and applications of configurations and methods for improved copper distribution uniformity in printed wiring boards have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. An electronic device comprising:
a dielectric substrate having a first surface and a second surface, and a via connecting the first and second surface, wherein the via has a horizontal cross sectional area;
a first and a second sacrificial copper structure coupled to the first and the second surface and surrounding the via, respectively, wherein each of the first and second sacrificial copper structures covers an area of no more than three times the horizontal cross sectional area of the via; and
wherein the first and the second sacrificial copper structures are formed on the substrate via a photolithographic process.

2. The electronic device of claim 1 wherein the substrate comprises a wiring board.

3. The electronic device of claim 2 wherein the first and the second surface of the dielectric material comprise a copper layer.

4. The electronic device of claim 1 wherein the via has a via surface, and wherein the via surface comprises copper.

5. The electronic device of claim 4 wherein the copper of the via surface and the first and second sacrificial copper structure are formed in a single process.

6. The electronic device of claim 1 wherein the via has a via diameter, wherein the first and second sacrificial copper structures have a first and second structure diameter, respectively, and wherein at least one of the first and second structure diameters are 150 microns larger than the via diameter.

7. The electronic device of claim 1 further comprising a via fill material disposed within the via.

8. The electronic device of claim 7 wherein the via fill material comprises a resin.

9. The electronic device of claim 7, wherein the via fill material is further disposed on the substrate in an area other than the via, and further comprising a photoresist layer between the first surface and the via fill material.

10. The electronic device of claim 1 wherein each of the first and second sacrificial copper structures covers an area of no more than two times the horizontal cross sectional area of the via.

11. A method of manufacturing an electronic device, comprising:
providing a dielectric substrate with a first surface and a second surface, and forming a via that connects the first and second surface, wherein the via has a horizontal cross sectional area;
forming in a photolithographic process a first and a second sacrificial electrically conductive structure on the first and the second surface and surrounding the via, respectively, wherein each of the first and second sacrificial copper structures covers an area of no more than three times the horizontal cross sectional area of the via; and
filling the via with a via fill material, and removing the first and second sacrificial copper structures.

12. The method of claim 11 wherein at least one of the first and second surfaces further comprise a copper layer.

13. The method of claim 11 wherein the via has a via surface, and wherein the via surface comprises copper.

14. The method of claim 13 wherein the copper of the via surface and the first and second sacrificial copper structure are formed in a single process.

15. The method of claim 11 wherein the via fill material comprises a resin.

16. The method of claim 11 wherein the step of removing the via fill material comprises mechanical abrasion.

17. The method of claim 11 wherein the step of forming the first and second sacrificial copper structures comprises forming a photoresist layer on the first and second surface, respectively, and wherein the photoresist layer is removed prior to the step of removing the first and second sacrificial copper structures.

18. The method of claim 11 wherein each of the first and second sacrificial copper structures covers an area of no more than two times the horizontal cross sectional area of the via.

19. The method of claim 11 wherein the area of the first sacrificial copper structure is different from the area of the second sacrificial copper structure.

20. The method of claim 11 further comprising forming at least one of a nickel layer and a gold layer on the at least one of the first and second surface.
